(19) United States
(12) Patent Application Publication
(10) Pub. No.: US 2009/0194023 A1
(43) Pub. Date: Aug. 6, 2009

(54) Plasma processing apparatus

(75) Inventor: Kazunari Tamura, Yamaguchi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kanagawa (JP)

(21) Appl. No.: 12/320,262

(22) Filed: Jan. 22, 2009

(30) Foreign Application Priority Data
Feb. 1, 2008 (JP) 22944/2008

(51) Int. Cl. C23C 16/54

(52) U.S. Cl. 118/708; 118/723 I

(57) ABSTRACT

A plasma processing apparatus is provided which can suppress variation in the electrode impedance varying due to a product or the like attached in a processing chamber, and which prevents variation in electric power consumed for plasma. According to the present invention, a plasma processing apparatus comprises a radiofrequency power supply 5 outputting radiofrequency power with reference to GND; a switching device 24 connected to the radiofrequency power supply; a lower electrode 2 connected to the switching device 24; an impedance control device 22 connected between the lower electrode 2 and GND; an impedance measuring device 23 connected between the switching device 24 and GND; and a controller 26 controlling the impedance control device 22 according to the value of impedance (the electrode impedance) measured by the impedance measuring device 23.

### BACKGROUND OF THE INVENTION

1. Field of the Invention

The present invention relates to a semiconductor manufacturing apparatus.

2. Description of Related Art

In an apparatus for performing processing treatment by means of plasma (hereinafter referred to as “plasma processing apparatus”), plasma discharge during processing is one of important parameters that determine processing characteristics.

With such an apparatus, however, there is a problem that the power consumed by plasma is not constant and the state of processing is unstable. This is caused by the variation of the plasma impedance in the processing chamber due to deposition in a processing chamber of reaction products produced during processing and due to individual variations of component parts in the processing chamber.

With the miniaturization of semiconductor circuit elements, improving the stability of processing with plasma discharge at the time of processing is becoming increasingly important.

Regarding a technique relating to impedance control, Japanese Patent Publication No. 60-206028 (Patent Document 1) discloses that a configuration of a plasma control apparatus, which constantly monitors the plasma impedance varying during plasma processing, makes the plasma impedance constant by feeding back the monitored plasma impedance to a gas supply system, in order to stabilize plasma discharge.

Japanese Patent Publication No. 2003-142455 (Patent Document 2) discloses a plasma processing apparatus and method which enable obtaining plasma with improved stability while minimizing the power loss, as described below. An impedance measuring device is provided at an electrode. The impedance and the phase value from the electrode to a vacuum processing chamber during plasma discharge are measured to estimate and determine the state of plasma and the state of power loss. To perform adjustment to a capacitive impedance, the permittivity in the chamber is changed by finely adjusting, on the basis of the estimation results, process condition parameters including the gas flow rate, pressure and temperature in such a range as not deviate from process conditions, and by changing the distance between the electrodes with a motor. Plasma can be obtained with improved stability by performing impedance adjustment in this way.

Japanese Patent Publication No. 2002-316040 (Patent Document 3) discloses a plasma processing apparatus and method in which an impedance measuring device capable of measuring the impedance in an electricity feed line between a load-side electrode and an impedance matching device during plasma discharge is provided and the measurement result is fed back to an impedance controller to minimize the power loss due to an inductance component produced in the electricity feed line.

The following analyses are given by the present invention: In the plasma processing apparatuses described in Patent Documents 1 to 3, the matching circuit for performing impedance matching with respect to radiofrequency power supplied from the radiofrequency power supply to the processing chamber performs control so that the resultant impedance of the processing chamber and the matching circuit is a constant value at all times in order to prevent reflected waves to the radiofrequency power supply. Since the interior of the actual processing chamber is constituted by various parts, there is a need to consider the impedance in the region, in which plasma is formed (plasma impedance), and the impedance in the region, in which plasma is not formed between the lower electrode and GND (electrode impedance), as the impedance in the processing chamber. As a reaction product is deposited in the vicinity of the lower electrode by plasma processing, the electrode impedance (mainly the electrostatic capacity component) changes with time due to the intrinsic permittivity of the product. Also, when a component part (typically a peripheral part of the lower electrode) is changed at the time of maintenance of the processing chamber, the electrode impedance changes due to the influence of an individual variation in impedance of the component part. Further, even when the component part is not changed, the impedance may change due to the influence of an assembled state of the component part.

### SUMMARY

According to the present invention, there is provided a plasma processing apparatus comprising: a radiofrequency power supply outputting radiofrequency power with reference to a reference potential; a switching device connected to the radiofrequency power supply; an electrode connected to the switching device; an impedance control device connected between the electrode and the reference potential; an impedance measuring device connected between the switching device and the reference potential; and a controller controlling the impedance control device according to the value of impedance measured by the impedance measuring device. In the plasma processing apparatus, the switching device connects the electrode to the radiofrequency power supply during plasma processing, and connects the electrode to the impedance measuring device when the impedance measuring device measures impedance between the switching device and the reference potential.

According to the present invention, variation in the electrode impedance varying with time due to a product or the like attached in the processing chamber can be suppressed to enable prevention of variation in radiofrequency power consumed for plasma (power which passes to the reference potential side without being consumed as plasma (power loss)). As a result, the power consumed for plasma is stabilized to enable stabilization of the state of processing characteristics during plasma processing.

### BRIEF DESCRIPTION OF THE DRAWINGS

The above and other objects, advantages and features of the present invention will be more apparent from the following description of certain preferred modes taken in conjunction with the accompanying drawings, in which:

FIG. 1 is a diagram showing an arrangement in a first embodiment of the present invention;

FIG. 2 is a diagram showing an equivalent circuit for the first embodiment of the present invention;

FIG. 3 shows a top view of a lower electrode, an electrically conductive ring and a dielectric member seen from the wafer mount surface side (the upper figure), and a sectional view taken along line A-A in the upper figure (the lower figure); and

FIG. 4 is a diagram showing an arrangement in a second embodiment of the present invention.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

A plasma processing equipment according to a first embodiment of the present invention will be described with reference to the attached drawings.

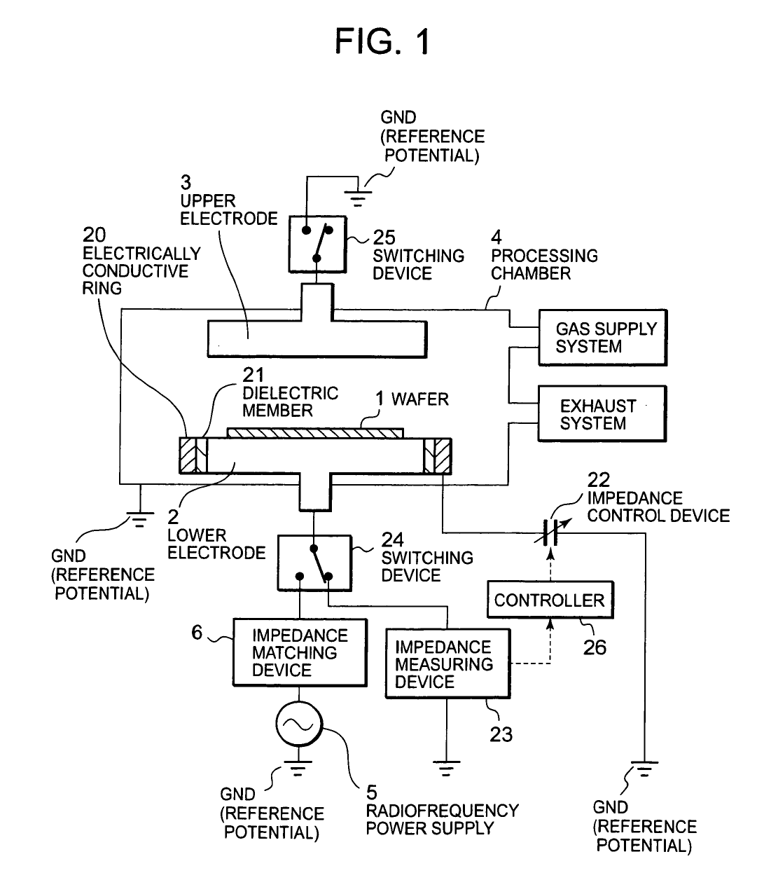

FIG. 1 is a diagram schematically showing an arrangement for a plasma processing apparatus according to a first embodiment of the present invention. In FIG. 1, the electrically conductive member (electrically conductive ring) 20 is provided in the vicinity of an outer peripheral portion of the lower electrode 2. The dielectric member 21 formed of an insulating material is provided between the electrically conductive ring 20 and the lower electrode 2. A capacitor is formed between the electrically conductive ring 20 and the lower electrode 2. That is, the dielectric member 21 acts as a dielectric for the capacitor formed between the electrically conductive ring 20 and the lower electrode 2.

It is not necessary to separately provide the dielectric member 21 when a surface treatment for forming an insulating film by anodization or the like is performed on one or both of the lower electrode 2 and the electrically conductive ring 20. This is because the surface-treated portion functions as the dielectric member 21.

The electrically conductive ring 20 is connected to one end of the impedance control device 22, and the other end of the impedance control device 22 is grounded (to the reference potential).

In the line for supplying radiofrequency power to the lower electrode 2, the switching device 24 is provided. The switching device 24 may make switchover by disconnecting the lower electrode 2 from the impedance matching device 6 and connect the lower electrode 2 to the impedance measuring device 23. The switching device 24 may include a switch.

On the upper electrode 3 side, the switching device 25 is provided in order to disconnect the upper electrode 3 from GND (the reference potential). The switching device 25 may include a switch.

The controller 26 controls the impedance control device 22 on the basis of a value monitored with the impedance measuring device 23.

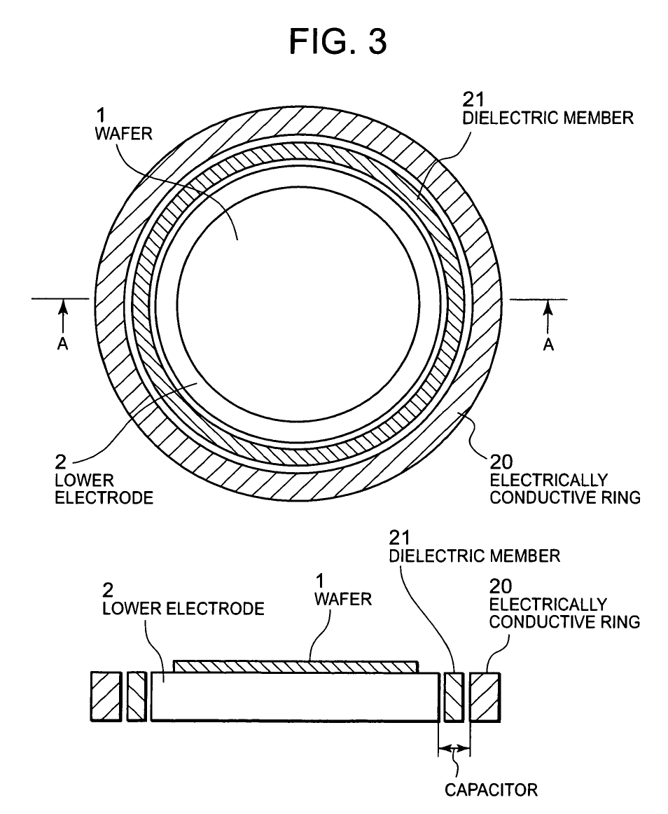

The upper figure in FIG. 3 is a plan view of the lower electrode 2, the electrically conductive ring 20 and the dielectric member 21 as seen from the wafer 1 mount surface side. The lower figure in FIG. 3 is a sectional view taken along line A-A in the upper figure in FIG. 3. The dielectric member 21 is placed in the gap between the lower electrode 2 and the electrically conductive ring 20 to form a capacitor.

Referring again to FIG. 1, a process material gas is supplied to the processing chamber 4 via a piping (gas supply system), and pressure control in the processing chamber 4 is performed by means of an exhaust system to maintain a constant pressure.

When radiofrequency power is applied to the lower electrode 2 from the radiofrequency power supply 5, the switching device 24 is operated so that the lower electrode 2 is connected to the impedance matching device 6 and the switching device 25 is also operated so that the upper electrode 3 is grounded. Radiofrequency power from the radiofrequency power supply 5 is applied to the lower electrode 2 in the processing chamber 4 via the impedance matching device 6 to form plasma between the lower electrode 2 and the upper electrode 3.

The impedance matching device 6 performs impedance matching so that radiofrequency power is efficiently supplied to the processing chamber 4. This impedance matching using the impedance matching device 6 is performed every time plasma processing is performed for generating plasma.

The switching device 24 can switch the connection of the lower electrode 2 to the impedance measuring device 23 according to arbitrary timing. Simultaneously (in synchronization) with the timing of this switching, the switching device 25 disconnects the upper electrode 3 from GND (the reference potential).

Switchover with the switching device 24 at a time other than times during plasma processing enables the impedance measuring device 23 to measure the electrode impedance of the processing chamber 4 which includes the impedance between the lower electrode 2 and the processing chamber connected to GND, and the impedance between the lower electrode 2 and GND through the capacitor (between the electrically conductive ring 20 and the lower electrode 2) and the impedance control device 22. The impedance measuring device 23 does not measure the impedance values of the upper electrode 3, the radiofrequency power supply 5 and the impedance matching device 6.

The electrode impedance changes when repeating plasma processing due to forming the deposition of plasma processing on the lower electrode 2 or between the lower electrode 2 and the processing chamber 4. To perform impedance control on the basis of the result of measurement with the impedance measuring device 23 so that the electrode impedance has a constant value, the controller 26 changes the impedance of the impedance control device 22 so that the impedance value measured with the impedance measuring device 23 becomes equal to a value set in advance. The impedance control device 22 is, for example, a variable capacitor.

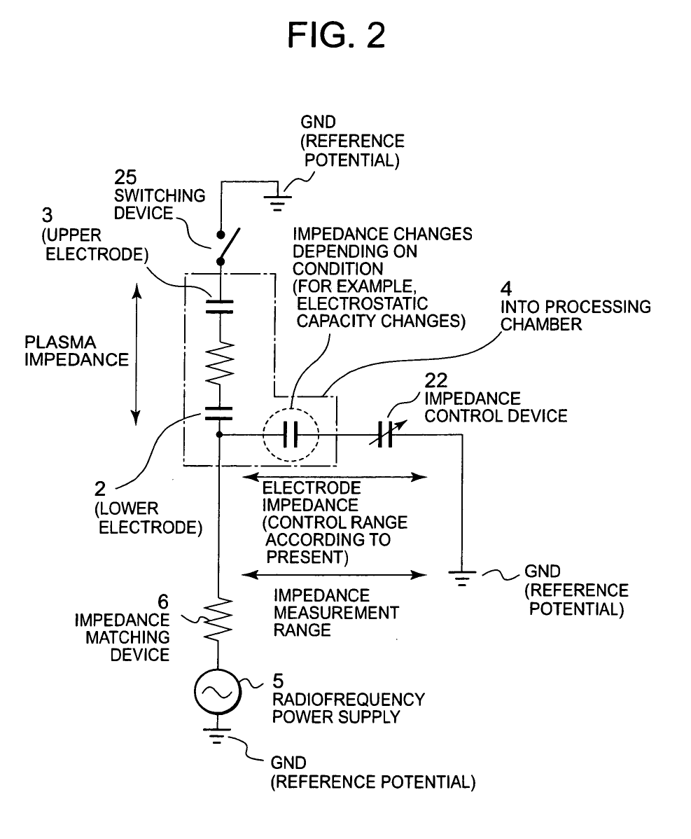

FIG. 2 is an equivalent circuit diagram of the first embodiment shown in FIG. 1. The switching device 25 disconnects the upper electrode 3 from GND; the lower electrode 2 is connected to the impedance measuring device 23; the lower electrode 2 and the electrically conductive ring 20, between which the dielectric member 21 is interposed, form an electrode of a capacitor connected to one end of the impedance control device 22 (variable capacitor); and the other end of the impedance control device 22 (variable capacitor) is connected to GND. As shown in FIG. 2, the lower electrode 2 in FIG. 1 has two capacitor components: the capacitor 2 in FIG. 2 and a part of the capacitor labeled as “IMPEDANCE CHANGES DEPENDING ON CONDITION” in FIG. 2. In FIG. 2, the electrode impedance is expressed by a series circuit formed by the capacitor labeled as “IMPEDANCE CHANGES DEPENDING ON CONDITION” (a part of lower electrode 2, dielectric member 21 and electrically conductive ring 20 in FIG. 1) and the impedance control device 22 (variable capacitor). The electrode impedance includes the impedance variation due to the deposition, such as a reaction product, which is unintentionally piled up on the lower electrode 2 during the plasma processing. The impedance measuring device 23 in FIG. 1 may measure the electrode impedance with the impedance variation due to the deposition.

According to the present embodiment, the value of the electrode impedance (between lower electrode 2 and GND) changing with time is constantly maintained at a predetermined value to enable prevention of variation in radiofrequency power which passes to GND side without being consumed as plasma in the radiofrequency power supplied to the lower electrode 2. In this way, variation in the power consumed for plasma is prevented to enable constant stabilization of the state of processing characteristic, such as an in-plane uniformity of etching rate in a wafer or variation of time for an etching rate.

This embodiment also enable to keep the same plasma condition after cleaning the lower electrode 2 due to removing the deposition formed during the plasma processing and exchanging new one of the lower electrode 2.

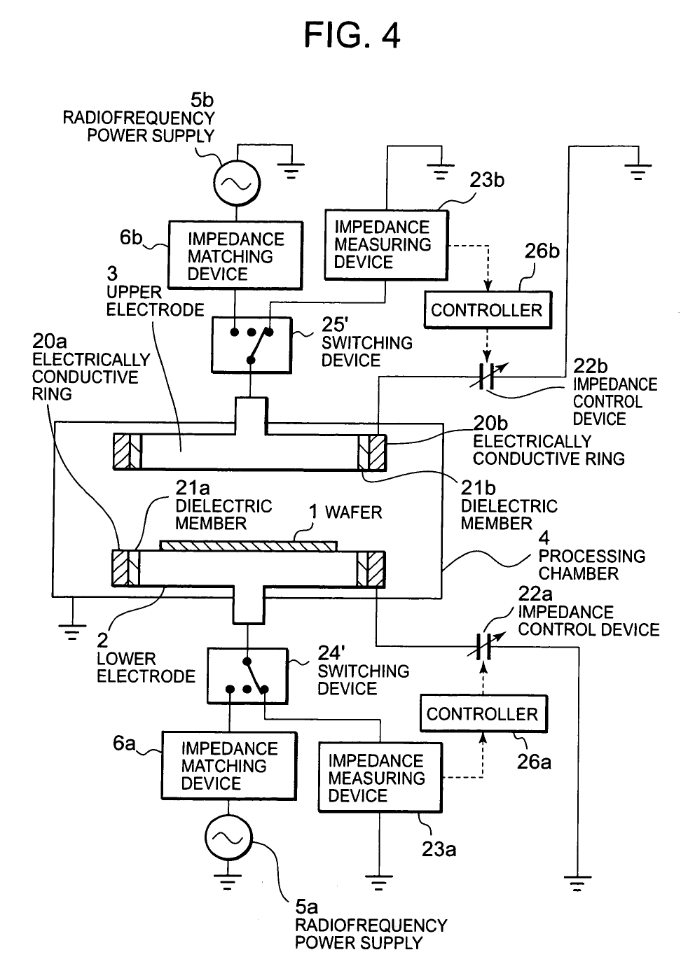

FIG. 4 is a diagram schematically showing an arrangement for a two-frequency-type plasma processing apparatus according to a second embodiment of the present invention. In the second embodiment of the present invention, the same arrangement as the mechanism for control of the electrode impedance of the lower electrode 2 described above with respect to the first embodiment is used for control of the electrode impedance of the upper electrode 3. In FIG. 4, reference numeral 1 denotes a wafer; reference numeral 2, a lower electrode on which the wafer 1 is placed; reference numeral 3, an upper electrode (third electrode); and reference numeral 4, a processing chamber. The lower electrode 2 is used as an electrode for ion energy control, while the upper electrode 3 is used as a radiofrequency application electrode for plasma density control.

In the present embodiment, a radiofrequency power supply 5a (first radiofrequency power supply) and a radiofrequency power supply 5b (second radiofrequency power supply), an impedance control device 22a (first impedance control device) and an impedance control device 22b (second impedance control device), an impedance measuring device 23a (first impedance measuring device) and an impedance measuring device 23b (second impedance measuring device), and an electrode impedance controller 26a (first controller) and an electrode impedance controller 26b (second controller) are provided in association with the lower electrode 2 (first electrode) and the upper electrode 3 (third electrode), respectively.

The lower electrode 2 has a dielectric member 21a and an electrically conductive ring 20a, as does that in the first embodiment. The connection of the lower electrode 2 is changed by means of a switching device 24′ between a position at which the lower electrode 2 is connected to an impedance matching device 6a, an intermediate position at which the lower electrode 2 is disconnected from each of the impedance matching device 6a and the impedance measuring device 23a, and a position at which the lower electrode 2 is connected to the impedance measuring device 23a. The electrically conductive ring 20a is connected to one end of the impedance control device 22a, while the other end of the impedance control device 22a is connected to GND.

The upper electrode 3 has a dielectric member 21b and an electrically conductive ring 20b, as does the lower electrode 2. The connection of the upper electrode 3 is changed by means of a switching device 25′ between a position at which the upper electrode 3 is connected to an impedance matching device 6b, an intermediate position at which the upper electrode 3 is disconnected from each of the impedance matching device 6b and the impedance measuring device 23b, and a position at which the upper electrode 3 is connected to the impedance measuring device 23b. The electrically conductive ring 20b is connected to one end of the impedance control device 22b, while the other end of the impedance control device 22b is connected to GND.

The operations of the switching devices 24′ and 25′ at the time of electrode impedance measurement in the present embodiment will be described. The switching devices 24′ and 25′ may include switches.

When the electrode impedance of the lower electrode 2 is measured, the switching device 24′ changes to the impedance measuring device 23a side. By the same timing as the timing of this change, the switching device 25′ changes to the intermediate position at which the upper electrode 3 is disconnected from each of the impedance matching device 6b and the impedance measuring device 23b. In this state, the impedance measuring device 23a measures the electrode impedance of the lower electrode 2.

When the electrode impedance of the upper electrode 3 is measured, measurement is performed by reversing the positions of the switching devices 24′ and 25′ from those at the time of measurement of the electrode impedance of the lower electrode 2. The switching device 25′ changes to the impedance measuring device 23b side. By the same timing as the timing of this change, the switching device 24′ changes to the intermediate position at which the lower electrode 2 is disconnected from each of the impedance matching device 6a and the impedance measuring device 23a. In this state, the impedance measuring device 23b measures the electrode impedance of the upper electrode 3.

In the case of plasma impedance adjustment (in the related art) through parameters such as the kind of gas, the gas flow rate, the pressure, the discharge power, the temperature and the distance between the electrodes, it is impossible to simultaneously adjust the impedances of the upper and lower electrodes. In the present embodiment of the present invention, the impedances may be independently controlled.

In the case of the apparatus having the arrangement for simultaneously applying two frequencies, radiofrequency powers are independently applied to the electrodes to control the plasma density and ion energy. Constant maintenance of the plasma density and ion energy in stable conditions is important in improving the stability of the state of working.

The functions and effects of the present embodiment will be described below.

Variation in the electrode impedance varying with time due to a product or the like attached in the processing chamber can be suppressed to prevent variation in electric power consumed for plasma. Therefore, the state of process working during plasma processing can be stabilized at all times to improve the manufacturing quality.

Also, the maintenance time for restoring the original value of the electrode impedance changed by the product can be reduced and the productivity can be improved.

Variation in the electrode impedance varying under the influence of a change in impedance due to an individual variation of a component part (typically a peripheral part of the electrode) changed at the time of maintenance in the interior of the processing chamber and under the influence of an assembled state of the component part after dismounting and mounting of the component part can be suppressed to prevent variation in electric power consumed for plasma. As a result, the state of process working can be stabilized at all times and the manufacturing quality can be improved.

Also, variation in the electrode impedance between a point in time before maintenance and a point in time after maintenance can be suppressed to achieve a reduction in maintenance time as well as to improve the productivity.

Comparisons with the related art will be described.

In the plasma processing apparatuses described in Patent Documents 1 to 3, the matching circuit for performing impedance matching with respect to radiofrequency power supplied from the radiofrequency power supply to the processing chamber performs control so that the resultant impedance of the processing chamber and the matching circuit is a constant value at all times in order to prevent reflected waves to the radiofrequency power supply. Since the interior of the actual processing chamber is constituted by various parts, there is a need to consider, as the impedance in the processing chamber, the impedance in the region in which plasma is formed (plasma impedance) and the impedance in the region in which plasma is not formed between the lower electrode and GND (electrode impedance).

According to the present invention, adjustment is performed by means of the impedance control device so that the electrode impedance does not vary. It is, therefore, possible to prevent a change in electrode impedance due to the permittivity of a reaction product as a result of the deposition of the reaction product in the vicinity of the lower electrode with the progress of plasma processing. Further, when a component part (typically a peripheral part of the lower electrode) is changed at the time of maintenance of the processing chamber, it is possible to prevent a change in electrode impedance due to the influence of an individual variation in the impedance value of the component part.

In the inventions described in Patent Documents 1 and 2, there is a need to change, according to the amount of change in impedance, process parameters such as the kind of gas, the gas flow rate, the pressure, the discharge power, the temperature and the distance between the electrodes important in the plasma working process.

On the other hand, in the present invention, these process parameters are not changed. The present invention therefore has the advantage of avoiding the influence of changing the parameters on the state of working including the etching rate and the shape.

In the invention described in Patent Document 3, the impedance in the electricity feed line between the output side of the impedance matching device and the electrode in the processing chamber is controlled.

On the other hand, in the present invention, variation in the electrode impedance can be prevented, so that the power consumed for plasma can be stabilized.

It is apparent that the present invention is not limited to the above embodiments, and the embodiments can be modified and changed as appropriately within the scope of the technical concept of the present invention.

What is claimed is:

1. A plasma processing apparatus comprising:
a radiofrequency power supply outputting radiofrequency power with reference to a reference potential;
a switching device connected to the radiofrequency power supply;
an electrode connected to the switching device;
an impedance control device connected between the electrode and the reference potential;
an impedance measuring device connected between the switching device and the reference potential; and
a controller controlling the impedance control device according to the value of impedance measured by the impedance measuring device,
wherein the switching device connects the electrode to the radiofrequency power supply at the time of plasma processing, and connects the electrode to the impedance measuring device when the impedance measuring device performs impedance measurement.

2. The plasma processing apparatus according to claim 1, wherein the electrode is a first electrode and the switching device is a first switching device, the plasma processing apparatus further comprising:
a second electrode placed by being opposed to the first electrode; and
a second switching device connected between the second electrode and the reference potential, the switching device connecting the second electrode to the reference potential at the time of the plasma processing, the switching device disconnecting the second electrode from the reference potential at the time of the impedance measurement.

3. The plasma processing apparatus according to claim 2, wherein plasma is generated by radiofrequency power applied between the first electrode and the second electrode during the plasma processing.

4. The plasma processing apparatus according to claim 3, wherein the first electrode and the impedance control device are connected through a capacitor.

5. The plasma processing apparatus according to claim 4, wherein one electrode of the capacitor is formed by the first electrode.

6. The plasma processing apparatus according to claim 5, wherein the capacitor has:
the first electrode;
a dielectric member formed on a side surface of the first electrode; and
an electrically conductive member formed in contact with the dielectric member and apart from the first electrode, the electrically conductive member being connected to the impedance control device.

7. The plasma processing apparatus according to claim 6, wherein the first switching device includes a switch, and the second switching device includes a switch.

8. The plasma processing apparatus according to claim 6, wherein the impedance control device has a variable capacitor.

9. The plasma processing apparatus according to claim 1, wherein the reference potential is ground.

10. The plasma processing apparatus according to claim 1, wherein the controller controls the impedance control device so that the value of impedance measured by the impedance measuring device is equal to a predetermined value.

11. The plasma processing apparatus according to claim 1, wherein the radiofrequency power supply is a first radiofrequency power supply; the switching device is a first switching device; the impedance control device is a first impedance control device; and the impedance measuring device is a first impedance measuring device, the plasma processing apparatus further comprising:
a second radiofrequency power supply which outputs radiofrequency power with reference to the reference potential;
a third switching device connected to the radiofrequency power supply;
a third electrode connected to the third switching device;
a second impedance control device connected between the third electrode and the reference potential;
a second impedance measuring device connected between the third switching device and the reference potential; and
a second controller which controls the second impedance control device according to the value of impedance measured by the second impedance measuring device,
wherein, at the time of plasma processing, the first switching device connects the first radiofrequency power supply and the first electrode to each other and the third switching device connects the second radiofrequency power supply to the third electrode to each other,
wherein, when the first impedance measuring device performs impedance measurement, the first switching device connects the first impedance measuring device and the first electrode to each other, and the third switching device electrically isolates the third electrode from the second radiofrequency power supply and the second impedance measuring device, and
wherein, when the second impedance measuring device performs impedance measurement, the first switching device electrically isolates the first electrode from the first radiofrequency power supply and the first impedance measuring device, and the third switching device connects the second impedance measuring device and the third electrode to each other.

12. The plasma processing apparatus according to claim 11, wherein the first controller controls the first impedance control device so that the value of impedance measured by the first impedance measuring device is equal to a predetermined value, and the second controller controls the second impedance control device so that the value of impedance measured by the second impedance measuring device is equal to a predetermined value.

13. The plasma processing apparatus according to claim 12, wherein the first electrode and the first impedance control device are connected through a first capacitor, or the third electrode and the second impedance control device are connected through a second capacitor.

14. The plasma processing apparatus according to claim 13, wherein the first capacitor has:
a first dielectric member formed on a side surface of the first electrode; and
a first electrically conductive member formed in contact with the first dielectric member and apart from the first electrode, the first electrically conductive member being connected to the first impedance control device.

15. The plasma processing apparatus according to claim 13, wherein the second capacitor has:
a second dielectric member formed on a side surface of the third electrode; and
a second electrically conductive member formed in contact with the second dielectric member and apart from the third electrode, the second electrically conductive member being connected to the second impedance control device.
